(19) United States
(12) Patent Application Publication
(10) Pub. No.: US 2005/0229964 A1
(43) Pub. Date: Oct. 20, 2005

(54) Method and system for self-electrical generation, storage, distribution and supply through an interchange between light and electricity

(75) Inventors: Lawrance Liao, Rancho Palos Verdes, CA (US); Jean Liao, Rancho Palos Verdes, CA (US); Pamela Liao, Rancho Palos Verdes, CA (US); Susan Liao, Rancho Palos Verdes, CA (US)

Correspondence Address: HDSL, 4331 STEVENS BATTLE LANE, FAIRFAX, VA, 22033, US

(73) Assignee: Easy Harvest Enterprise Company LTD.

(21) Appl. No.: 11/105,440

(22) Filed: Apr. 14, 2005

(30) Foreign Application Priority Data
Apr. 14, 2004 (TW) 093110307

(51) Int. Cl. H01L 31/00

(52) U.S. Cl. 136/252; 136/248

(57) ABSTRACT

A method and system for self-electrical generation, storage, distribution and supply through an interchange between a light energy and an electrical energy includes a photovoltaic module, an artificial light source, a battery assembly, leading wire, circuit, electronic automatic controlling element and component and loading. The solar light energy can be employed to activate the photovoltaic module to generate electrical energy, which will be provided to the artificial light source with a proper wavelength inside the box, so that the multi-surfaces photovoltaic module disposed on the inner wall of the hollow structure object can be illuminated to generate a large quantity of electrical energy, or when there is no sunshine, the artificial light source can be charged directly by the electrical energy from a battery or other artificial seed electrical energy for illuminating the multi-surface photovoltaic module disposed on the inner wall of the hollow structure object with a proper wavelength so that the multi-surface photovoltaic module may generate a large quantity of electrical energy, which may be stored or used. The scale of this system can be designed and disposed according to the practical demands and safely modulated and used. Moreover, this system also can be designed as a detachable and portable equipment in addition to a fixed manner.

### BACKGROUND OF THE INVENTION

The present invention is related to a system and method of disposing a multi-surface photovoltaic (pv) module on an inner wall of a hollow structure object (e.g, an inner wall of a cubic box or other suitable shapes) which is uniformly illuminated by an artificial light source with a proper wavelength so as to cause the multi-surface photovoltaic module to generate an electrical energy, which is greater than which is consumed by the artificial light source and can be properly stored and used. Before that, in addition to the hollow structure object, a photovoltaic module with a sufficient power should be needed for providing a seed electrical energy to the artificial light source, or a battery or other artificial electrical sources should be needed for providing the seed electrical energy, so as to obtain an artificial light energy with a suitable wavelength. According to the present invention, the solar light energy can be a seed energy for the system to activate the photovoltaic module mounted outside the box for generating the seed electrical energy, which provides the artificial light source inside the box, or when there is no sunshine or the sunshine is insufficient, the artificial light source with a suitable wavelength inside the box can be directly charged by the electrical energy from a battery or other artificial seed electrical energy for uniformly illuminating the multi-surface photovoltaic module disposed on the inner wall of the hollow structure object so that the multi-surface photovoltaic module may generate a large quantity of electrical energy larger than which is consumed by the artificial light source. Take a cubic box as an example. Because the box is composed of six side surfaces, the artificial light source should uniformly illuminate the six-surface photovoltaic module disposed on the inner wall of the box so as to generate a large quantity of electrical energy. Through modulations of all kinds of electronic controlling elements and components, converter, inverter, circuit, leading wire, loading and electrical energy storage apparatus etc., which are reasonably and safely allocated, the obtained electrical energy can achieve a sustained and stable electrical energy supply. Furthermore, the system according to the present invention also can be designed to have smaller hollow structure objects disposed in a larger hollow structure object so as to more efficiently and widely gather the energy and save the volume occupied by the system.

Since human discover the electricity, the electrical energy significantly improves the human life and also achieves amazing advancement in material civilization. Because the extremely dependency and requirement, people continuously search for all kinds of energy for being transformed into the electrical energy. However, under the large-scale and grasping developments and destructions from human, the earth we relied on now has pounced back gradually and quietly, for example, greenhouse effect, El Nino, various pollutions, desertification, acid rain etc., which are almost caused by industrialization. Obviously, the price for limitless desire and deeply industrialization is the dried up energy resource and environmental pollutions and probably the self-destruction of human beings.

In the recent three, four decades, because the environmental pollution is getting serious and the climate becomes unusual, people finally find that the highly polluted petrochemistry and nuclear energy, which are employed to generate energy resources, should be abandoned. And, because inside the sun, the thermonuclear reactions are proceeded continuously, just like millions of hydrogen bombs explode simultaneously per second (regardless of the difference between the practical reaction and the hydrogen bomb), these “explosions” provide a large quantity of light and heat. Furthermore, because the sun owns a massive mass, before the sun becomes a red giant, there still has fifty hundred million years. That is to say, before the sun is exhausted, people should utilize it well to develop a better energy so that before the solar system is destructed, people may “escape” to another galaxies for continuing human life.

The photovoltaic effect is firstly developed by a French physicist Edmund Becquerel in 1839, and however, the basic theory thereof is further realized by people until 1930s because the development of quantum mechanics. Therefore, the research and development of the photovoltaic cell are also improved thereby. And, owing to the early stage of space development between United States and Soviet Russia, the practicability thereof is also proved.

Photovoltaic cell can be separated into single crystalline, polycrystalline and amorphous. The single crystalline cell can be made of single crystalline silicon and has the highest efficiency, which has a theoretical threshold up to 29%. The efficiency of the polycrystalline silicon cell is slightly lower than the single one, but because of the low cost, the polycrystalline silicon cell is used more extensively. As to the amorphous silicon cell, such as thin film cell, although the cost is low, the efficiency thereof is also low, and therefore, it is usually used in small electronic products with a lower power consumption. In addition, the semiconductor GaAs cell also employs single crystalline, but, because the cost thereof is extremely high, it is only used for particular purpose.

Presently, because of the purpose and the limitation of efficiency and cost, the the photovoltaic generator is always arrayed with large area. In some advanced countries, for more effective usage of the solar energy to generate electrical power, many dwelling houses, business buildings, schools and hospitals adopt photovoltaic modules or panels and redesign them as decorations. There are also some fabrications make the pv modules become pv tiles. All these designs or products can provide free electricity after a proper electrical distribution, buffer, converter and control system. Moreover, it also can be communicated with the commercial electricity system so that when at night, rainy, or insufficient sunshine owing to latitude or season, the regulator and converter may automatically switch to the commercial electricity for maintaining operation. On the contrary, the surplus electrical energy generated by pv modules can also be feedback to the commercial electricity system.

Because pv electricity generation system is still limited by technical and weather conditions, it should consider the solar spectrum, clearness index, air mass (AM), environmental conditions, such as surrounding temperature, topography, wind direction, wind power, relative humidity, heat attack, hailstone, snowfall, rainfall, sunshine and latitude etc. Furthermore, the mechanical and electric standard of the selected material also should be carefully and comprehensively considered for obtaining safe and reasonable benefit. Therefore, because these conditions are severely limited, the idea of solar electricity generation is still not popular even though all governments have provided excellent rewards.

### SUMMARY OF THE INVENTION

The present invention is to provide a method and system for self-electrical generation, storage, distribution and supply through an interchange between a light energy and an electrical energy so as to reduce a mine of oil or natural resources and stop building and operation of nuclear power station or other types of power station for reducing the pollutions, and further protect the earth environment and human existence.

Another, the present invention is to provide a method and system for self electrical generation, storage, distribution and supply through an interchange between a light energy and an electrical energy which can stably generate, store, distribute and supply electrical energy in a whole new and economical mode for electricity provision so that people can heartily enjoy the electronic equipments and technology without worrying the power bill.

Further, the present invention is to provide a method and system for self electrical generation, storage, distribution and supply through an interchange between a light energy and an electrical energy which will not be limited by the day and night, climate, region and latitude and can break through the large-scale array of the conventional solar power generation system so that the limitations of area and other natural conditions can be reduced, and also, the probability of being destroyed by wind and snow, earthquake and dust-storm can be reduced so as to continuously generate a non-polluted electrical energy.

Still further, the present invention is to provide a method and system for self electrical generation, storage, distribution and supply through an interchange between a light energy and an electrical energy which is an independent, low-cost and high efficiency method and apparatus and can help the remote districts to develop more quickly or provide the power for the desalination process of sea water.

Still further, the present invention is to provide a method and system for self electrical generation, storage, distribution and supply through an interchange between a light energy and an electrical energy which make an independent electric equipment no longer be limited by the network power source.

Still further, the present invention is to provide a method and system for self electrical generation, storage, distribution and supply through an interchange between a light energy and an electrical energy so that the power of an internal combustion engine can be replaced by a free and clean electrical power.

Still further, the present invention is to provide a method and system for self electrical generation, storage, distribution and supply through an interchange between a light energy and an electrical energy so that the constraint of large-scale central power supply network can be thrown off and a small-scale and independent type can be developed for gathering unfailing electrical energy.

Still further, the present invention is to provide a method and system for self electrical generation, storage, distribution and supply through an interchange between a light energy and an electrical energy which can reduce the high density electric cables arrangement, save the cost of mounting and maintaining the electric cables, and reduce the danger and occurrence of fire caused by improper usage of electric wire.

Still further, the present invention is to provide a method and system for self electrical generation, storage, distribution and supply through an interchange between a light energy and an electrical energy which is detachable and portable so that it can be a temporary power for particular purposes, such as outdoor activity, traveling, construction sites, battle zones or meeting.

Still further, the present invention is to provide a method and system for self electrical generation, storage, distribution and supply through an interchange between a light energy and an electrical energy, wherein it only needs to reserve the seed electrical energy or provide the seed electrical energy by a primitive manual manner so that even at a frozen and snow-covered land or region of forever night, the photovoltaic module can also be activated successfully to generate electrical energy.

Accordingly, the present invention subverts the conventional arrangement and disposition of photovoltaic module or large-scale array. That is to say, the present photovoltaic module, pv panel or pv array is disposed in a box and not faced the sunlight, which is replaced by an artificial light source.

The present invention assembles the photovoltaic module on an inner wall of a hollow structure object, e.g., box, triangle, polygon, sphere or other suitable shapes, so that it cannot be recognized as an electricity generator from appearance. Take a cubic box as an example. The artificial light source with a proper wavelength is positioned at a central point of the box for uniformly illuminating the six-surface photovoltaic module disposed on the inner wall of the box so as to generate a large quantity of electrical energy. Moreover, another photovoltaic module can be mounted on the top of the box or other suitable positions for gathering the solar energy to be transformed into an electrical energy as the seed electrical energy for the artificial light source inside the box. Therefore, through this arrangement, this system can generate an electrical energy larger than which is consumed by the artificial light source. Take a cubic box with four sides of 1 m as an example. The photovoltaic module with normal rated power 150 w/m² is disposed to have an area of 2 m² and at a position with sufficient sunlight for gathering 300 W power. Then, the power is provided to the artificial light source of approximately 300 W so as to emit a particular wavelength to uniformly illuminate six surfaces of photovoltaic module disposed on the inner wall of the box. Assume that each surface of pv module has a normal rated power of 150 w/m², 900 W power will be generated (without considering the minor shadow caused by the artificial light source and the leading wire, resistance and other consumptions). If the obtained 900 W power is averagely transformed and transmitted to other three 300 W artificial light sources so as to simultaneously illuminate pv module on the inner walls of other three identical cubic boxes, 2700 W power would be obtained, and so forth, infinite electrical energy can be obtained, too. Certainly, the consumed power of the artificial light source should be deducted from the calculated electrical power. However, significant electrical energy still can be “remained” for storage and utilization.

The obtained electrical energy described above can be provided to loading or battery system via a proper design and also can be provided to the artificial light source in the same system. Moreover, it can be merged into a commercial electricity system. Through a proper designed and arranged automatic controlling electronic element and component, such as converter, voltage controller, power regulator, filter or filter circuit, commutator, frequency generator, pulse width modulation (PWM) control element, power conditioning equipment, bridge circuit, protection circuit, semiconductor switch element (SCR, silicon control regulator), electric meter and leakage current detector, leading wire and circuit system, grid-connected, line-commutated inverter etc., this system may develop an extremely great benefit and also solve many problems about energy. If there is a necessity to be communicated with the commercial electricity system, it also can be designed to have bi-directional interchange through monitoring, coordination and switch systems, which are all well known in the prior art and will not be given unnecessary details here.

Besides, if this system needs to be initiated at night or under insufficient sunlight, the seed electrical energy can firstly be provided by the battery or other artificial power supply, and the electricity generation can be proceeded immediately. Then, the automatic control system within this system can feedback the electricity to the battery or other power storing equipment, which provides the seed electrical energy, so as to provide loading and also maintain the operation of the artificial light source. The system according to the present invention also can be used in a light transportation carrier for replacing the internal combustion engine. It can always see that the solar car must be equipped with a photovoltaic module as a very large plate at the top of the car. But, now, through the design of the present invention, the large plate is no longer needed, and even more, it can run in the rainy day or at dark night because the power is continuously generated from the inside of the power generating boxes of the system. Therefore, the climate or the sunshine is no longer the limitation of the solar electricity generation system. And, the only consideration is to fix the components of the whole system for avoiding the shake of the transportation carrier as moving.

The only disadvantage of the present invention is that both the artificial light source with a particular wavelength and power storing equipment have a particular life-span, and thus, a periodical maintenance and replacement is necessary. For detecting the need of replacement of the artificial light, in the system, a checking window having a structure or installation can be opened and closed can be mounted on the box structure object of the pv module, and a procedure of sending a detecting and warning signal is also necessary, too. As the signal reveals that the artificial light source is broken down or should be replaced, a turn-off switch should be existed for turning off the power freely so that the user can open the checking window for replacement and so as the battery equipment and other circuit element and components. It is absolutely that the prerequisite condition for utilizing this non-polluted and quiet system is safety.

In addition, because the box is a hollow structure object and the artificial light source is disposed thereinside and operated continuously, the material and ventilation of the box should be properly selected for ensuring a correct and safe operation.

Regarding the electronic controlling elements and components, leading wire, circuit, artificial source, spectrum, variety of battery and various quantum mechanics and photovoltaic theories and manufacturing method thereof which are needed by the present invention, theses are all familiar to one skilled in this art and have been widely used in some products, and thus, please allow not give details here.

### BRIEF DESCRIPTION OF THE DRAWINGS

The drawings disclose an illustrative embodiment of the present invention which serves to exemplify the various advantages and objects hereof, and are as follows:

FIG. 1 is a framework showing an indoor system according to the present invention;

FIG. 2 is an application illustration according to the present invention;

FIG. 3 is a framework showing a comprehensive system according to the present invention;

FIG. 4 is an illustration showing a portable hollow structure object; and

FIG. 5 is an illustration showing a variation of a portable hollow structure object according to the present invention.

### DETAILED DESCRIPTION OF THE PREFERRED EMBODIMENT

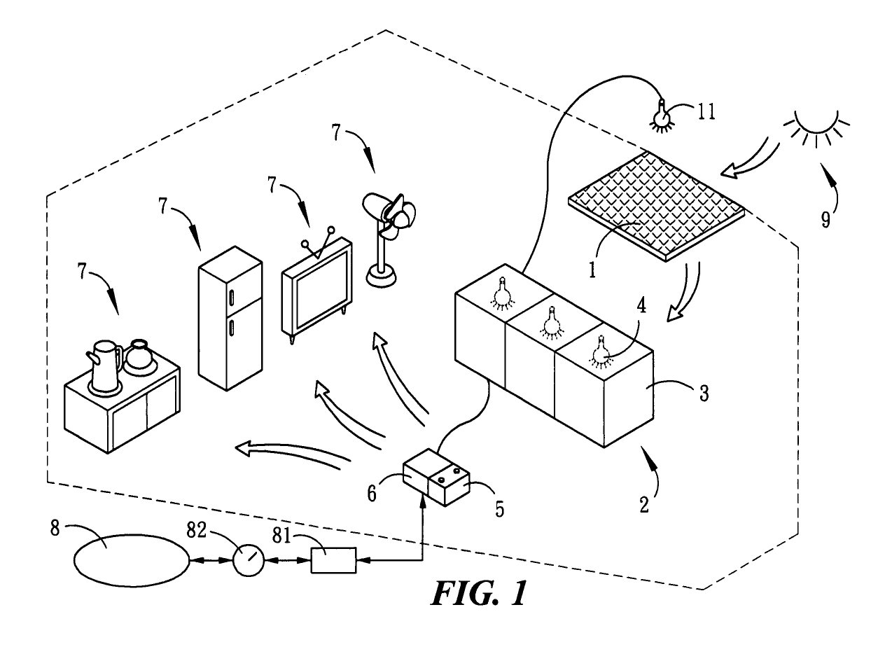

Please refer to FIG. 1. The present invention provides a method and system for self electrical generation, storage, distribution and supply through an interchange between a light energy and an electrical energy. In this embodiment, a dwelling house is taken as an example. The system includes an external photovoltaic module 3, which is exposed to the sunshine, an inner photovoltaic module 3 (also see FIG. 4) mounted in a hollow structure object 2, an artificial light source 4 with a proper wavelength, a battery assembly 5, an automatic controlling circuit box 6, a loading 7, a commercial electricity network system 8, an interface controller 81, which is compatible with the commercial electricity network system, and some necessary control circuits and protection circuits.

When sunlight 9 illuminates the outdoor external pv module 1, the outdoor external pv module 1 will immediately generate an electrical energy to provide the artificial light source 4. Then, the artificial light source 4 will emit a particular wavelength having a normal rated power for uniformly illuminating the inner pv module 3 mounted in each hollow structure object 2, wherein because each hollow structure object 2 has six surfaces, three objects 2 will have eighteen surfaces. The eighteen surfaces of the inner pv module 3 will immediately generate multiple of electrical energy, which is then transmitted to the loading 7 and the battery assembly 5 via the automatic controlling circuit box 6 for electrical distribution, supply and storage. Therefore, when at night or the sunshine is insufficient and the outdoor external pv module 1 does not generate electrical energy any more, the automatic controlling circuit box 6 will switch from the distribution and supply mechanism to the battery assembly 5 for continuously supplying electrical energy to the artificial light source 4. And, as the battery assembly 5 has been discharged to a certain level, the automatic controlling circuit box 6 will again switch to the charging mechanism and the battery assembly 5 will be recharged by the inner pv module 3. In the system according to the present invention, when the electrical used energy is low, the automatic controlling circuit box 6 will self-detect and activate the commercial electricity comparable interface controller 81 to feed the surplus electrical energy into the commercial electricity network system 8 through an electric meter 82, and vice versa.

If necessary, an artificial light source 11 with a proper wavelength can be mounted at a corresponding position to the outdoor external pv module 1 for independent illumination or illumination by reflection so that the external pv module 1 still can be illuminated at night If this arrangement is still conformed to the economical benefit after estimation, it can be considered to be carried out for gathering more electrical energy. Namely, in addition to the solar energy, the seed electrical energy also can be transformed from other artificial electrical energy. Besides, a proper deposition of a mirror or optical material inside the hollow structure object 2 can also promote the efficiency of the artificial light source 4.

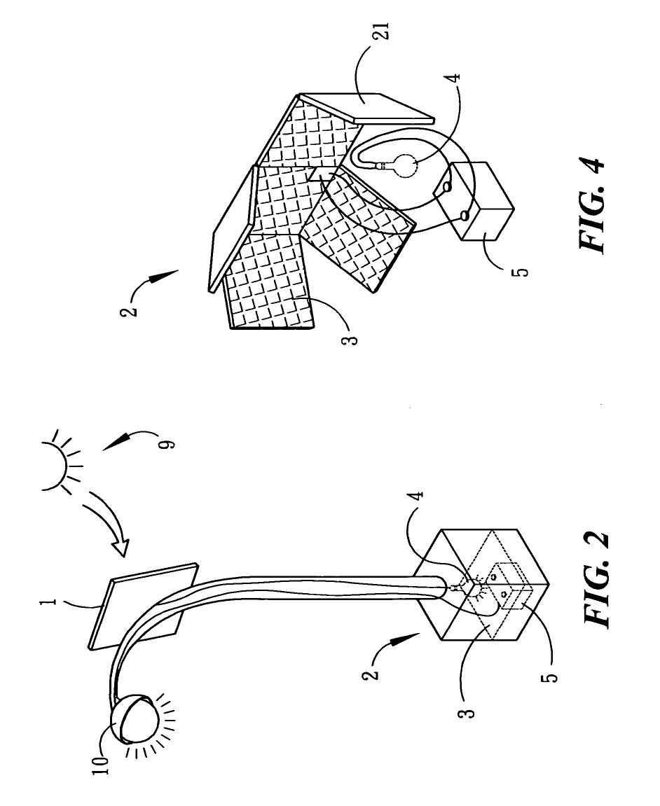

Please refer to FIG. 2. The present invention provides a method and system for self electrical generation, storage, distribution and supply through an interchange between a light energy and an electrical energy. In this embodiment, a streetlight 10 is taken as an example and this is a situation of independent electric equipment The system includes a hollow structure object 2, an inner pv module 3 mounted inside the hollow structure object 2 and having six surfaces, an artificial light source 4 with a proper wavelength, a pv module 1 exposed to the sunlight 9, a battery assembly 5, some necessary control circuits and protection circuits and an external armored or protection device outside the hollow structure object 2. When operating, firstly, the external pv module 1 exposed to the sunshine will gather the sunlight 9 and immediately transform the sunlight to an electrical energy for providing the artificial light source 4. Then, the artificial light source 4 will uniformly illuminate the inner pv module 3 inside the hollow structure object 3 so as to generate a large quantity of electrical energy. The generated electrical energy is stored by the battery assembly 5 through a transportation of the control circuit system and prepared for the streetlight 10 at night. This is advantageous that multiple electrical energy can be stored so that no matter in the plum rains season or in winter with shorter sunshine, there still has stored seed electrical energy, and an intelligent self control can make the streetlight to be turned on or off on time and not limited by the conventional solar electricity generation system, which is useless under bad weather and insufficient sunshine.

The above described hollow structure object may have a shape of box, triangle, polygon, sphere or other suitable shapes and can be an independent or combined object depending on the demand. And, the hollow structure also can have a checking window and an indicating meter mounted thereon and a warning signal for ensuring a correct operation of the system.

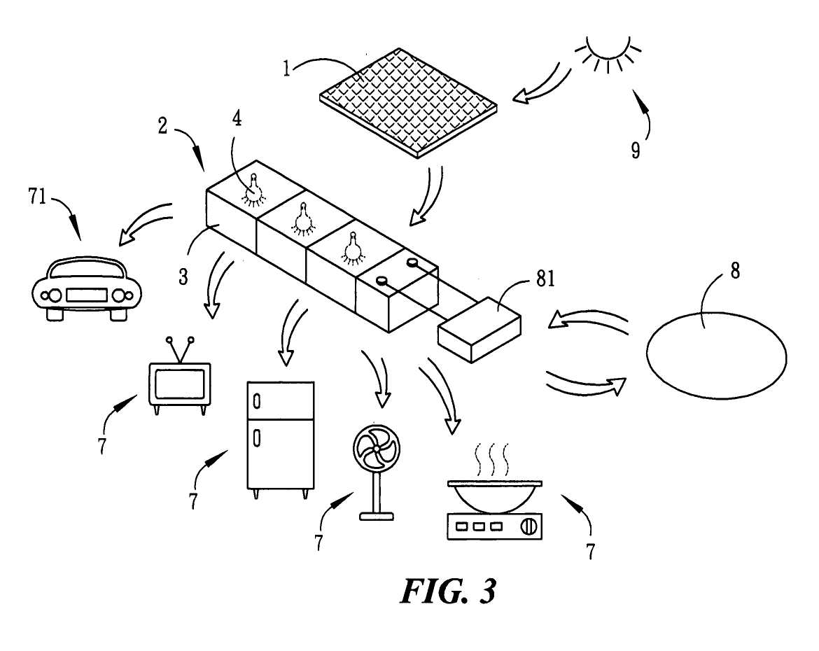

Please refer to FIG. 3 showing a comprehensive electricity generation, storage, distribution and supply system. Different from FIG. 1, this embodiment is not limited in resident usage. It can be distributed to multiple loadings 7, be suitable for reducing coal combustion and oil consumption and provide clean power source. In addition, the present invention also can be applied in a transportation carrier 71 to replace the power of an internal combustion engine.

Please refer to FIG. 4. The hollow structure object 2 according to the present invention can be detachable and portable and composed of multiple plate bodies 21, which are assembled and fixed by screw, bolts or engagement. The inner wall of each plate body 21 has an inner photovoltaic module 3 mounted thereon so that a system for electrical generation, storage, distribution and supply by an interchange between a light energy and an electrical energy can be easily achieved through cooperation with the portable artificial light source 1, battery assembly 5 and proper control circuit.

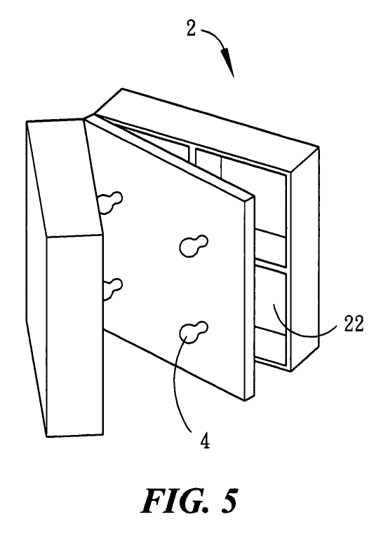

Please refer to FIG. 5. For more efficiently and widely gathering the energy and saving the volume occupied by the system, in the present invention, the inner space of the larger hollow structure object 2 is reasonably separated into several smaller hollow structure objects 22, and each smaller hollow structure object 22 may have an artificial light source 4 positioned therein. Although there will need more lower power artificial light sources 4 to be positioned in this kind of installation, the total area of plural hollow structure objects 22 will be significantly larger than that of only one hollow structure object 2, and thus, the overall efficiency can be improved.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

1. A method for electrical generation, storage, distribution and supply through an interchange between a light energy and an electrical energy, comprising the steps of:
activating an artificial light source having a proper wavelength by a seed electrical energy so that the artificial light source illuminates a photovoltaic module, which is fully disposed on an inner wall of a hollow structure, a great quantity of electrical energy is generated by the photovoltaic module and then storing and utilizing the electrical energy through a modulation and a protection of all kinds of automatic electronic controlling elements, components and circuits.

2. The method according to claim 1, further comprising the step of supplying the generated electrical energy for self-operation, loading and storage and further provided for communicating and interchanging with commercial electricity.

3. The method according to claim 1, wherein the generated electrical energy replaces a power of an internal combustion engine when being used in a transportation carrier.

4. A system for electrical generation, storage, distribution and supply through an interchange between a light energy and an electrical energy, comprising:
a hollow structure object;
a plurality of photovoltaic modules mounted at an inner wall of the hollow structure object;
an artificial light source mounted inside the hollow structure object for illuminating the photovoltaic modules to generate the electrical energy; and
a seed electrical energy for providing an energy for activating the artificial light source.

5. The system according to claim 4, wherein the seed electrical energy is one of an artificial electrical energy or an electrical energy transformed from a solar energy.

6. The system according to claim 4, wherein the hollow structure object has a three-dimensional volume with a shape of one selected from a group consisting of a box, a triangle, a polygon, a sphere and other suitable shapes and is an independent or a combined object depending on the demand so as to expand a gathering efficiency of the energy and save a volume occupied by the system.

7. The system according to claim 4, wherein the hollow structure has a checking window and an indicating meter mounted thereon and a warning signal for ensuring a correct operation of the system.
